(19) United States
(12) Patent Application Publication
(10) Pub. No.: US 2019/0062894 A1
(43) Pub. Date: Feb. 28, 2019

(54) EVAPORATION MASK PLATE AND EVAPORATION METHOD

(71) Applicants: BOE TECHNOLOGY GROUP CO., LTD., Beijing (CN); CHENGDU BOE OPTOELECTRONICS TECHNOLOGY CO., LTD., Chengdu (CN)

(72) Inventors: Tingyan YANG, Beijing (CN); Chuanyou HE, Beijing (CN)

(21) Appl. No.: 15/994,259

(22) Filed: May 31, 2018

(30) Foreign Application Priority Data
Aug. 30, 2017 (CN) 201710764525.6

(51) Int. Cl. C23C 14/04; C23C 14/12; C23C 14/24; H01L 27/32; H01L 51/00

(52) U.S. Cl. CPC C23C 14/042; C23C 14/12; H01L 51/0011; H01L 27/3206; C23C 14/24

(57) ABSTRACT

An evaporation mask plate for a display substrate is provided. The display substrate includes a plurality of pixel units arranged in an array, and a dam is disposed in each of the pixel units. The evaporation mask plate includes a mask plate body and evaporation openings arranged on the mask plate body in an array. The evaporation openings run through the evaporation mask plate body and correspond to an area to be vapor-deposited of each pixel unit on the display substrate. The mask plate body includes a thinned region for covering the dam of the display substrate during evaporation and an active region located between the thinned region and the evaporation openings. The thickness of the thinned region is less than the thickness of the active region. An evaporation method adopting the evaporation mask plate is also provided.

The present disclosure claims priority of Chinese Patent Application No. 201710764525.6 filed on Aug. 30, 2017, the disclosure of which is hereby entirely incorporated by reference as a part of the present disclosure.

### TECHNICAL FIELD

Embodiments of the present disclosure relate to an evaporation mask plate and an evaporation method.

### BACKGROUND

In an OLED (Organic Light Emission Display, organic light emitting diode) manufacturing technology, an evaporation mask plate for vacuum evaporation is a crucial component, and the quality of the evaporation mask plate directly affects the production cost and product quality. At present, the vacuum evaporation technology is a fully developed and commonly used technology. During the OLED evaporation process, organic materials are deposited on a substrate located above the evaporation source to form a unique pattern. An evaporation mask plate is closely adhered to the substrate from below, and a pre-designed layout opening is disposed on the evaporation mask plate. Finally, the organic materials will be deposited on the substrate through the opening on the evaporation mask plate.

### SUMMARY

At least one embodiment of the present disclosure provides an evaporation mask plate for a display substrate, the display substrate comprising a plurality of pixel units arranged in an array, and a darn being disposed in each of the pixel units, wherein the evaporation mask plate comprises a mask plate body and evaporation openings arranged in the evaporation mask plate body in an array, the evaporation openings run through the evaporation mask plate body and correspond to an area to be vapor-deposited of each pixel unit on the display substrate, the evaporation mask plate body comprises a thinned region configured to cover the darn of the display substrate during evaporation and an active region located between the thinned region and the evaporation openings, and a thickness of the thinned region is less than a thickness of the active region.

In one embodiment of the present disclosure, the thickness of the thinned region is half of the thickness of the active region.

In one embodiment of the present disclosure, a shape of the evaporation openings is rectangular.

In one embodiment of the present disclosure, in each pixel unit, the thinned region is disposed surrounding the evaporation opening.

In one embodiment of the present disclosure, a shape of the thinned region is rectangular.

At least one embodiment of the present disclosure provides an evaporation method adopting the evaporation mask plate as mentioned above, comprising placing a display substrate to be vapor-deposited and an evaporation mask plate into an evaporation chamber; aligning the display substrate to be vapor-deposited with the evaporation mask plate, so that the active region of the mask plate abuts on the display substrate to be vapor-deposited and the thinned region covers the dam of the display substrate; performing evaporation on the display substrate to be vapor-deposited by use of an evaporation source; and after the evaporation is completed, removing the evaporation mask plate and the display substrate having been vapor-deposited.

At least one embodiment of the present disclosure provides an evaporation method adopting the evaporation mask plate as mentioned above, comprising placing a display substrate to be vapor-deposited and an evaporation mask plate into an evaporation chamber in which a magnetic device is provided; in a state that the magnetic device is off, aligning the display substrate to be vapor-deposited with the evaporation mask plate; after the alignment is completed, turning on the magnetic device so as to generate a magnetic force, so that the evaporation mask plate is tightly adhered to the display substrate to be vapor-deposited under action of the magnetic force; performing evaporation on the display substrate to be vapor-deposited by use of an evaporation source; and after the vapor deposition is completed, turning off the magnetic device and removing the evaporation mask plate and the display substrate having been vapor-deposited.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1 is an illustrative structural view of an evaporation mask plate according to one embodiment of the present disclosure;

FIG. 2 is an illustrative cross-sectional view of the evaporation mask plate illustrated in FIG. 1 taken along A-A;

FIG. 3 is a partial illustrative view of an evaporation process of an evaporation mask plate according to one embodiment of the present disclosure;

FIG. 4 is a flow chart of a manufacturing method of an evaporation mask plate according to one embodiment of the present disclosure;

FIG. 5 is an illustrative flow chart of a first patterning process in the manufacturing method of the evaporation mask plate according to another embodiment of the present disclosure;

FIG. 6 is an illustrative flow chart of a second patterning process in the manufacturing method of the evaporation mask plate according to another embodiment of the present disclosure;

FIG. 7 is an illustrative flow chart of an evaporation process of an evaporation mask plate according to yet another embodiment of the present disclosure; and

FIG. 8 is an illustrative flow chart of an evaporation process of an evaporation mask plate according to still another embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

In the OLED manufacturing technology, before the evaporation process, a glass substrate has been provided with a raised dam, which is mainly used to support a packaged glass cover plate, and during the evaporation process, since there is a gap between the evaporation mask plate and the glass substrate, evaporation materials can be easily mixed into the gap to generate a mura defect, which affects the quality of the vapor deposition and ultimately affects the display effect of the display panel.

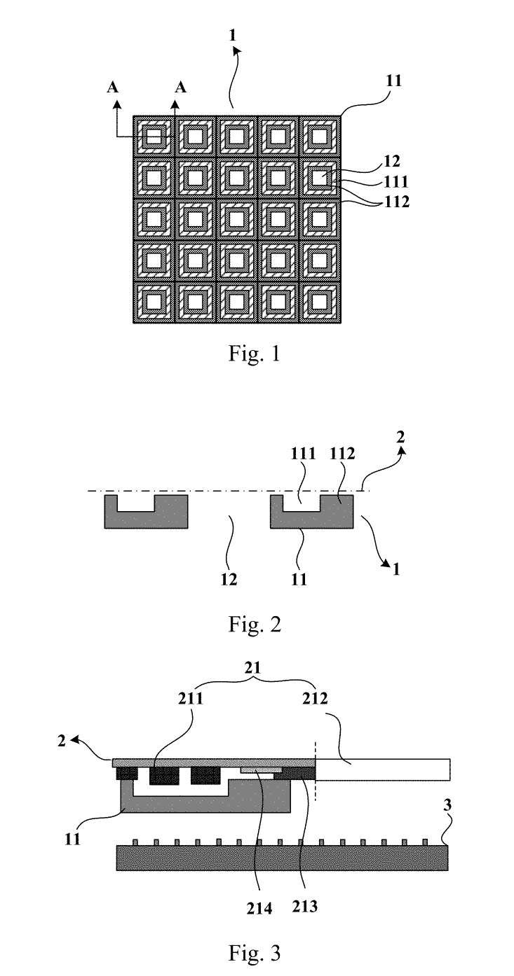

With reference to FIG. 1, FIG. 2 and FIG. 3, at least one embodiment of the present disclosure provides an evaporation mask plate 1 for vapor deposition a display substrate 2. The display substrate 2 comprises a plurality of pixel units 21 arranged in an array, and a darn 211 is disposed in each of the pixel units 21. The evaporation mask plate 1 comprises a mask plate body 11 and evaporation openings 12 arranged on the mask plate body 11 in an array. The evaporation openings 12 run through the mask plate body 11 and correspond to an area 212 to be vapor-deposited of each pixel unit 21 on the display substrate 2. The mask plate body 11 comprises a thinned region 111 for covering the dam 211 of the display substrate 2 during vapor deposition and an active region 112 located between the thinned region 111 and the evaporation openings 12. The thickness of the thinned region 111 is less than the thickness of the active region 112.

In the above-described technical solution, the thinned region is formed by partially etching an area of the evaporation mask plate corresponding to the dam of the display panel to be protected, and the thinned region and the evaporation openings corresponding to the area to be vapor-deposited of the display substrate are separated by the active region. The scheme for the evaporation mask plate can effectively reduce the gap between the evaporation mask plate and the display substrate at the evaporation openings while protecting the dam area of the display substrate from being pressed by the evaporation mask plate, thereby reducing the area affected by the shadows generated during vapor deposition, and improving the yield of the display panel. The scheme for the evaporation mask plate also facilitates the overlap of the cathode and anode film layers at an edge of the display substrate and the design of a narrow frame, thereby improving the display efficiency of the display panel.

In a practical evaporation process, for example, as illustrated in FIG. 2 and FIG. 3, the evaporation mask plate 1 is disposed between an evaporation source 3 and the display substrate, and is adhered to a side of the display substrate 2 on which the pixel unit 21 (comprising a pixel definition layer 213 and a dam 211) is provided. The evaporation openings 12 of the evaporation mask plate 1 correspond to the area 212 to be vapor-deposited on the display substrate 1, and the darn 211 is accommodated in the thinned region 111. The active region 112 in the mask plate body 11 abuts on the corresponding pixel definition layer in the display substrate 2. In addition, each of the pixel units 21 further has an electrode 214. In the embodiment of the present disclosure as illustrated in FIG. 3, the electrode 214 is an anode, and a cathode corresponding to the anode and to be overlapped with the anode is disposed at the edge of the display substrate.

The evaporation mask plate according to the embodiments of the present disclosure eliminates the gap between the evaporation mask plate and the display substrate during the evaporation, improves the tightness of adherence of the evaporation mask plate and the display substrate, reduces the risk of color mixing, and improves the evaporation quality. In addition, it can reduce the distance between the evaporation mask plate and the vapor-deposited pixel area, reduce the range affected by the shadow effect of vapor deposition, improve the effective evaporation area of the pixel units, and effectively improve the opening ratio. In addition, since the evaporation mask plate and the display substrate can form a mutually mating patterns, the dams in the display substrate can restrict the position of the evaporation mask plate, thereby avoiding a thermal deformation misalignment between the evaporation mask plate and the display substrate due to increase in the evaporation temperature.

In one embodiment of the present disclosure, a size of the thinned region of the evaporation mask plate is matched with a size of the dam. The size of the thinned region of the evaporation mask plate being matched with the size of the dam can make the alignment between the evaporation mask plate and the display substrate more accurate during the evaporation, thereby improving the evaporation quality. For example, the thickness of the thinned region is half of the thickness of the active region. A large number of experiments show that when the thickness of the thinned region is half of the thickness of the active region, the risk of color mixing can be reduced during the evaporation, and the range affected by the shadow effect of evaporation can be reduced.

In the embodiments of the present disclosure, the shape of the evaporation opening is not limited, and it can be selected according to various factors such as the requirement, the pattern and type of the display substrate, and the like at the time of production. For example, the shape of the evaporation opening in the evaporation mask plate is rectangular. Further, the thinned region of the evaporation mask plate is disposed surrounding the evaporation opening, but is not adjacent to the evaporation opening. And, the shape of the thinned region is also rectangular.

Deposition processes for the metal material, the planarization layer material, or the color filter layer of the display substrate are not limited in the embodiments of the present disclosure.

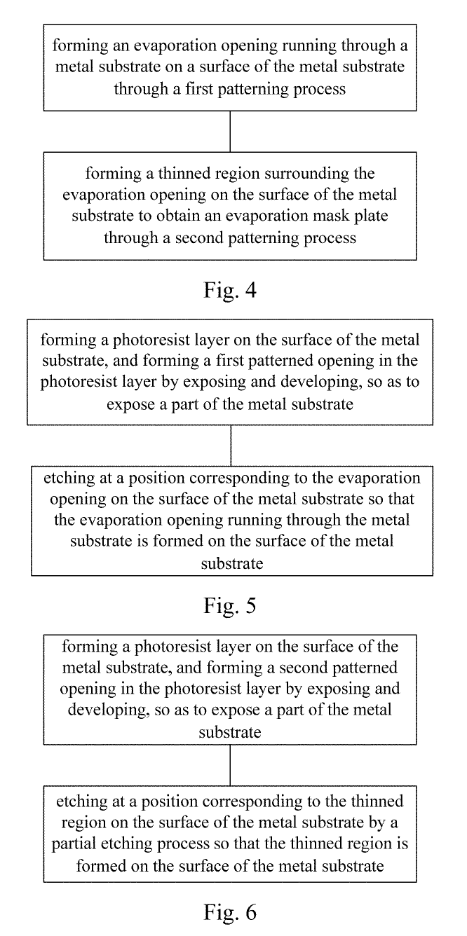

At least one embodiment of the present disclosure provides a method for manufacturing an evaporation mask plate, as illustrated in FIG. 4, comprising:

forming an evaporation opening running through a metal substrate on a surface of the metal substrate through a first patterning process; and

forming a thinned region surrounding the evaporation opening on the surface of the metal substrate to obtain an evaporation mask plate through a second patterning process.

Forming an evaporation opening running through the metal substrate on the surface of the metal substrate through the first patterning process, can comprise:

forming a photoresist layer on the surface of the metal substrate, and forming a first patterned opening in the photoresist layer by exposing and developing, so as to expose a part of the metal substrate;

etching at a position corresponding to the evaporation opening on the surface of the metal substrate so that the evaporation opening running through the metal substrate is formed on the surface of the metal substrate.

Forming a thinned region surrounding the evaporation opening on the surface of the metal substrate to obtain an evaporation mask plate through the second patterning process, can comprise:

forming a photoresist layer on the surface of the metal substrate, and forming a second patterned opening in the photoresist layer by exposing and developing, so as to expose a part of the metal substrate;

etching at a position corresponding to the thinned region on the surface of the metal substrate by a partial etching process so that the thinned region is formed on the surface of the metal substrate.

In the evaporation mask plate manufactured by the method according to the embodiments of the present disclosure, the thinned region is formed by partial etching the mask plate body in an area of the evaporation mask plate corresponding to the dam area of the display substrate to be protected, and the thinned region and the evaporation openings corresponding to the area to be vapor-deposited of the display substrate are separated by the active region. The evaporation mask plate can effectively reduce the gap between the evaporation openings of the evaporation mask plate and the display substrate while protecting the darn area of the display substrate from being pressed by the evaporation mask plate, thereby reducing the area affected by the shadows generated during evaporation, and improving the yield of the display panel. The evaporation mask plate also facilitates the overlap of the cathode and anode film layers at an edge of the display substrate and the design of a narrow frame, thereby improving the display efficiency of the display panel.

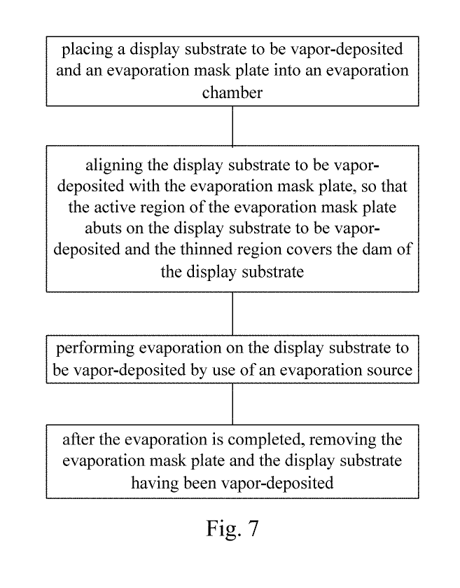

At least one embodiment of the present disclosure further provides an evaporation method adopting the above-described evaporation mask plate, as illustrated in FIG. 7, comprising:

placing a display substrate to be vapor-deposited and an evaporation mask plate into an evaporation chamber;

aligning the display substrate to be vapor-deposited with the evaporation mask plate, so that the active region of the evaporation mask plate abuts on the display substrate to be vapor-deposited and the thinned region covers the dam of the display substrate;

performing evaporation on the display substrate to be vapor-deposited by use of an evaporation source; and

after the evaporation is completed, removing the evaporation mask plate and the display substrate having been vapor-deposited.

The display substrate is subjected to a vapor deposition by the evaporation method. The evaporation mask plate has a thinned region corresponding to the dam area of the display substrate to be protected, and the thinned region and the evaporation openings corresponding to the area to be vapor-deposited of the display substrate are separated by the active region. The evaporation method can effectively reduce the gap between the evaporation mask plate and the display substrate to be vapor-deposited at the evaporation openings while protecting the dam area of the display substrate from being pressed by the evaporation mask plate, thereby reducing the area affected by the shadows generated during evaporation, and improving the yield of the display panel. The scheme for the evaporation mask plate also facilitates the overlap of the cathode and anode film layers at an edge of the display substrate and the design of a narrow frame, thereby improving the display efficiency of the display panel.

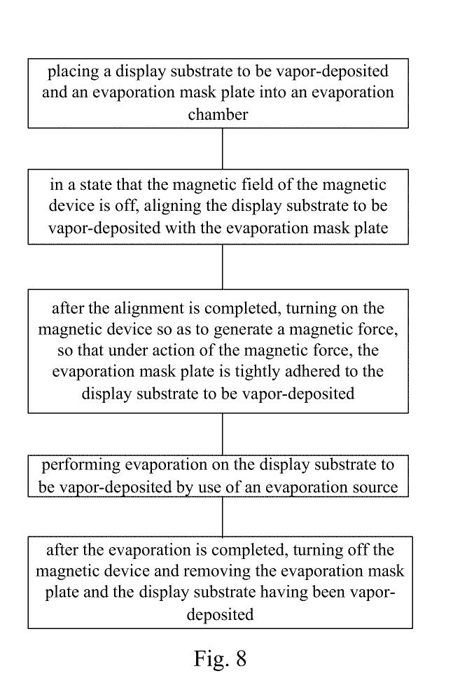

Further, as illustrated in FIG. 8, the evaporation method adopts electromagnetic evaporation, and a magnetic device is disposed in the evaporation chamber. The evaporation method comprises:

placing a display substrate to be vapor-deposited and an evaporation mask plate into an evaporation chamber;

in a state that the magnetic field of the magnetic device is off, aligning the display substrate to be vapor-deposited with the evaporation mask plate;

after the alignment is completed, turning on the magnetic device so as to generate a magnetic force, so that under action of the magnetic force, the evaporation mask plate is tightly adhered to the display substrate to be vapor-deposited;

performing evaporation on the display substrate to be vapor-deposited by use of an evaporation source; and

after the evaporation is completed, turning off the magnetic device and removing the evaporation mask plate and the display substrate having been vapor-deposited.

The evaporation method according to the above embodiment of the present disclosure adopts electromagnetic evaporation, which can provide more heat for evaporation source to be vaporized, and thus the evaporation rate is faster; and positioning of the electron beam is accurate, and thus the evaporation material can be prevented from being evaporated or contaminated.

The foregoing are merely exemplary embodiments of the disclosure, but are not used to limit the protection scope of the disclosure. The protection scope of the disclosure shall be defined by the attached claims.

1. An evaporation mask plate for a display substrate, the display substrate comprising a plurality of pixel units arranged in an array, and a dam being disposed in each of the pixel units, wherein the evaporation mask plate comprises a mask plate body and evaporation openings arranged in the evaporation mask plate body in an array, the evaporation openings run through the evaporation mask plate body and correspond to an area to be vapor-deposited of each pixel unit on the display substrate, the evaporation mask plate body comprises a thinned region configured to cover the dam of the display substrate during evaporation and an active region located between the thinned region and the evaporation openings, and a thickness of the thinned region is less than a thickness of the active region.

2. The evaporation mask plate according to claim 1, wherein the thickness of the thinned region is half of the thickness of the active region.

3. The evaporation mask plate according to claim 1, wherein a shape of the evaporation openings is rectangular.

4. The evaporation mask plate according to claim 3, wherein in each pixel unit, the thinned region is disposed surrounding the evaporation opening.

5. The evaporation mask plate according to claim 4, wherein a shape of the thinned region is rectangular.

6. An evaporation method adopting the evaporation mask plate according to claim I, comprising:
placing a display substrate to be vapor-deposited and an evaporation mask plate into an evaporation chamber;
aligning the display substrate to be vapor-deposited with the evaporation mask plate, so that the active region of the mask plate abuts on the display substrate to be vapor-deposited and the thinned region covers the dam of the display substrate;
performing evaporation on the display substrate to be vapor-deposited by use of an evaporation source; and
after the evaporation is completed, removing the evaporation mask plate and the display substrate having been vapor-deposited.

7. An evaporation method adopting the evaporation mask plate according to claim I, comprising:
placing a display substrate to be vapor-deposited and an evaporation mask plate into an evaporation chamber in which a magnetic device is provided;
in a state that the magnetic device is off, aligning the display substrate to be vapor-deposited with the evaporation mask plate;
after the alignment is completed, turning on the magnetic device so as to generate a magnetic force, so that the evaporation mask plate is tightly adhered to the display substrate to be vapor-deposited under action of the magnetic force;
performing evaporation on the display substrate to be vapor-deposited by use of an evaporation source; and
after the vapor deposition is completed, turning off the magnetic device and removing the evaporation mask plate and the display substrate having been vapor-deposited.
